(19) United States
(12) Patent Application Publication
(10) Pub. No.: US 2012/0231154 A1
(43) Pub. Date: Sep. 13, 2012

(54) CERAMIC DEVICE AND METHOD FOR FABRICATING THE SAME

(76) Inventors: Wen-Hsiung Liao, Hsinchu County (TW); Wen-Yu Lin, Taipei City (TW); Wei-Chien Chang, Hsinchu County (TW)

(21) Appl. No.: 13/353,322

(22) Filed: Jan. 19, 2012

(30) Foreign Application Priority Data
Mar. 11, 2011 (TW) 100108258

(51) Int. Cl. H05K 3/12; H05K 3/10

(52) U.S. Cl. 427/97.4; 427/97.3; 427/98.5

(57) ABSTRACT

A method for fabricating a ceramic device is provided. A green sheet is adhered on an adhesive film. A photoresist film is then formed on the green sheet. A photolithographic process is carried out to form circuit trenches in the photoresist film. The circuit trenches are filled with metal paste, thereby forming a circuit pattern. The photoresist film is then removed.

### BACKGROUND OF THE INVENTION

1. Field of the Invention

The present invention relates to a multilayer ceramic device, and more specifically, to a multilayer ceramic device having a fine lines circuit with high aspect ratio, and method for fabricating the same. The present invention also includes the steps for making green ceramic body and ceramic paste. The multilayer ceramic device in the present invention is especially suitable for high-precision ceramic components, IC carriers, multi-chip modules and weather-resistant circuit boards, etc.

2. Description of the Prior Art

In recent years, the trend in the field of portable information and mobile telecommunication technologies have been to develop lighter, compacter, more reliable, multi-functional and lower cost devices, which means electronic products with higher components density. For this reason, active and passive devices miniaturization, on chip integration and modularization have been improved to efficiently shrink the size of the circuits, thereby further lowering the cost and improving product competitiveness. Among those technologies, low-temperature co-fired ceramic (LTCC) is one of the most commonly used technique, since it allows conventional passive devices to be incorporated into multilayer ceramic substrate and be sintered into one integrated ceramic device, therefore reducing the size of device.

Low temperature co-fired ceramic technology utilizes ceramic material as the substrate. Ceramic powder and binding agent are mixed to form pulpous slurry. The slurry is transformed into sheets of thin green ceramic body by tape casting and drying process (referred as green sheets hereafter). The circuit pattern is then formed thereon by screen printing. Multiple through holes are punched on each layer of green ceramic to provide a route for signal transduction. The patterned holes are then filled with the paste to form electrodes. The required multiple layers of green sheets are laminated at a temperature below 1000° C. The metal and ceramic portions are sintered at the same time to form compact LTCC devices. Since the passive components, such as resistors, capacitors and inductors, are sintered within the same substrate, the once cumbersome circuit is now transformed into a multilayer integrated structure, thereby significantly reducing the size of electronic devices. The surface of the substrate may carry other devices, such as IC chips and transceivers, etc. This way, a complete system-in-package (SIP) module can be accordingly built.

However, the aspect ratio of the printed patterns made by screen printing in current industrial LTCC process is limited by the rheological and stripping properties of the glue material used in screen printing, especially when the mesh number and the emulsion thickness are fixed beforehand. It is impossible to obtain a multilayer ceramic device having a fine line circuit with high aspect ratio by using current conventional screen printing processes.

### SUMMARY OF THE INVENTION

The main purpose of the present invention is to provide an improved ceramic device and method for fabricating the same in order to avoid above-mentioned technology flaws and shortcomings.

One preferred embodiment of the present invention discloses a method for fabricating a ceramic device comprising the steps of providing an unsintered layer, coating a photoresist on said unsintered layer, forming a circuit trench in said photoresist by lithography process, filling a metal paste in said circuit trench to form circuit patterns, and removing said photoresist.

Another preferred embodiment of the present invention discloses a method for fabricating a ceramic device comprising the steps of: providing an unsintered layer, coating a first photoresist on said unsintered layer, forming a first circuit trench in said first photoresist by lithography process, filling a first metal paste in said first circuit trench to form a first circuit pattern, removing said first pattern, forming a dielectric layer on said unsintered layer and said first circuit pattern, wherein said dielectric layer includes an opening exposing a part of said first circuit pattern, covering a second photoresist on said dielectric layer, forming a second circuit trench in said second photoresist by lithography process, filling a second metal paste in said second circuit trench to form a second circuit pattern, and removing said second photoresist.

Another preferred embodiment of the present invention discloses a circuit structure of a ceramic device comprising a ceramic substrate and a silver circuit pattern having a high aspect ratio formed on the surface of said ceramic substrate, wherein the width of said silver circuit pattern is smaller than 50 μm, and the height of said silver circuit pattern is larger than 5 μm. The ceramic substrate contains silver elements that diffuse to the grain boundary due to the high sintering temperature.

These and other objectives of the present invention will be obvious to those of ordinary skill in the art after reading the following detailed description of the preferred embodiments that are illustrated in the following figures and drawings.

### BRIEF DESCRIPTION OF THE DRAWINGS

FIG. 1 illustrates a fabricating process flow for the ceramic device in accordance with the present invention.

FIGS. 2A-2D illustrate the process steps for a single-layer circuit structure of the ceramic device in accordance with the present invention.

FIGS. 2E-2H illustrate the process steps for a 2nd-level layer circuit structure (subsequent to FIG. 2D).

FIG. 3 illustrates the circuit structure of a ceramic device in accordance with the present invention.

FIGS. 4A-4C illustrate the cross-sectional view of fine line circuits with different dimensions and aspect ratios.

### DETAILED DESCRIPTION

In the field of relevant skill, an article entitled “Photo Patterned Conductors with LTCC for Microwave and High Density Interconnect” published by Peter Barnwell et al. provides a method for manufacturing 50 μm fine line circuits with controlled precision of 2.5pm and thickness of 10 μm (the sheet resistance is 2 mΩ), by utilizing photo-sensitive conductive glue material in photo-lithography process. The photo-sensitive conductive glue material consists mainly of conductive powder, photo-sensitive agents and binding agents. If the composition of the glue is rich in conductive powder, the light entering the glue materials will be reflected by the metal conductive powder during the exposure process. When the content of conductive powder is lower, the impedance of the device is higher.

It is mentioned in the Japan patent number JP 3545701 (B2) that the product is made by using printing technique to form a high aspect ratio circuit structure in order to efficiently improve the device's quality factor. Concerning the printing technique, high aspect ratio may be achieved by: (1) re-printing the conductive circuit, or (2) re-printing the insulating layer (or dielectric layer) to form a trench with high aspect ratio and then fill in the conductor material. These two processing methods may form jagged structure on the sidewalls due to the repeated printing processes. Thus, the sidewalls of the conductive circuit made by repeated printing process will be structurally different from the ones made by photolithography process

In addition, an article entitled “Thick Film Fine Line Patterning—A Definitive Discussion of the Alternatives” published by Meg Tredinnick et al. provides a method comprising printing and sintering a circuit on a substrate in advance, and then using photoresist to expose, develop and etch the sintered circuit, in order to improve the precision of circuit. The aforementioned method is suffering the disadvantage of: (1) limited width and thickness of circuit line, and (2) long process time.

Generally speaking, photolithography processes for thin-film devices like the one disclosed in US 2010/0091473, may include steps of forming a conductive adhesive layer with predetermined thickness by sputtering, chemical vapor deposition (CVD) or physical vapor deposition (PVD). A copper plating process is performed thereafter to form the circuit portion. In the structure made by this process, the interface between the substrate and the conductive layer is maintained mainly through physical adhesion, therefore the prior cleaning process of the adhesive layer is very important, since any organic substance may seriously contaminate the adhering surface; lowering the reliability of the following process and the efficiency of the product. During the process of low temperature co-fired ceramic (LTCC), the conductive material is bonded with a dielectric material or another insulating material by co-firing process. Organic substances at the interface are completely driven out during the co-firing step. The diffusion mechanism at the interface between the substrate and the conductive material is initiated when the temperature is high enough to start the atom diffusion, thereby improving the adhesiveness at the interface. An article entitled “Multilayer Chip Inductor” published in the proceedings of “Multilayer Electronic Ceramic Devices” describes the diffusion behavior of silver atoms directly influenced by the presence of chlorine (Cl)) or sulfur (S) compounds at the interface of the co-firing system.

Furthermore, the number of formed circuit layers and the structure of the products are limited by the process requirements for thin film devices (which forces the ceramic device to have predetermined thickness) and by the standard sizes and specifications of the components. The laminated LTCC process may adjust the thickness of the substrate and increase the number of circuit layers, according to the structure requirements. A LTCC process will have more margins in the design of product specification compared to a thin-film process.

More specifically, the present invention relates to a novel process technique. The technique combines the LTCC process with photolithography process to manufacture multilayer ceramic devices having fine line circuits with high aspect ratio. The present invention takes advantage of the high precision on dimension control in the photolithography process to produce circuits with fine line circuits and high aspect ratios. The LTCC process is incorporated in the method to adjust the compatibility among the co-fired materials, and obtain multilayer ceramic devices with high interface adhesiveness.

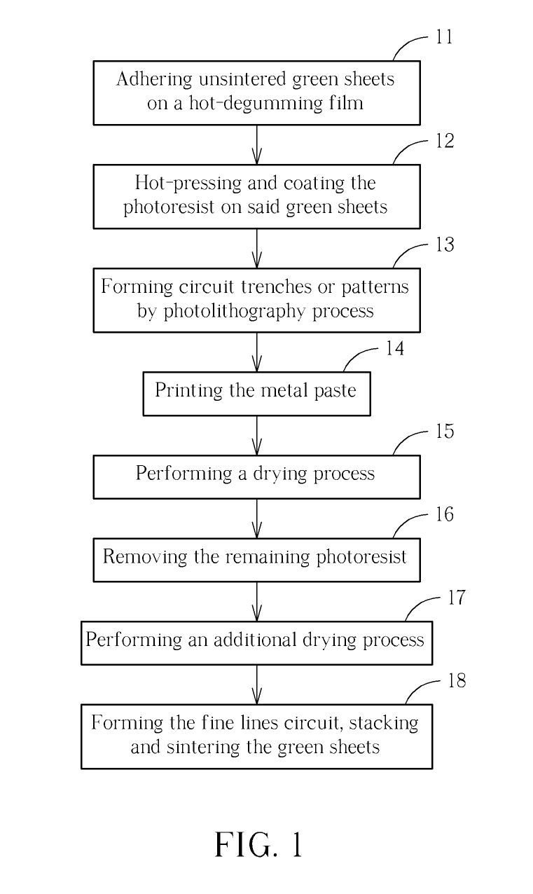

Please refer to FIG. 1. The process flow for manufacturing the ceramic device of the present invention comprises the steps of adhering unsintered green sheets (also referred hereinafter as unsintered layers) or dried ceramic film on a hot-degumming film (step 11), hot-pressing and coating the photoresist on said green sheets (step 12), forming circuit trenches or patterns by photolithography process (step 13), filling metal paste into said circuit trenches by thick film printing process (step 14), performing a drying process (step 15), then removing the remaining photoresist by etching, to keep desired circuit pattern and forming fine line circuits on said green sheets (step 16), performing an additional drying process (step 17); finally, after a plurality of fine lines circuit green sheets layers have been stacked into a 3D circuit structure, sintering the whole into a multilayer shaped substrate(step 18).

The materials required in the manufacturing method of present invention will be subjected to an acid/alkaline environment with high humidity rate, therefore the selected green sheet and glue material for printing must be acid/alkali-resistant and water-resistant. A lipid-soluble and acid/alkali-resistant organic carrier is therefore necessary in the formulation of the glue material. According to one preferred embodiment of present invention, the material of a green sheet may be ceramic powder combined with a lipid-soluble and acid/alkali-resistant binding agent, such as polyvinyl butyral (PVB). According to one preferred embodiment of the present invention, the glue material for printing may include metal powder, such as silver powder, copper powder or gold power, and a lipid-soluble and acid/alkali-resistant binding agent, such as polyvinyl butyral (PVB), which amount in the main powder may be comprised between 3% and 15 wt %, preferably 1012 wt %, considering the adhesiveness and the acid/alkali-resistance. The solvent used in present invention may be an organic solvent, such as terpineol. The glue material for printing may include additional plasticizer, such as dibutyl phthalate (DBP), which amount of the binding agent may range from 20% to 50 wt %, preferably 25˜35% considering the adhesiveness and the acid/alkali-resistance, in order to improve its adhesiveness, dispersibility, and uniformity characteristics.

The following embodiment further describes the present invention rather than limits the scope of present invention. Those skilled in the art will readily observe that numerous modifications and alterations of the device and method may be made while retaining the teachings of the invention.

### Embodiment 1

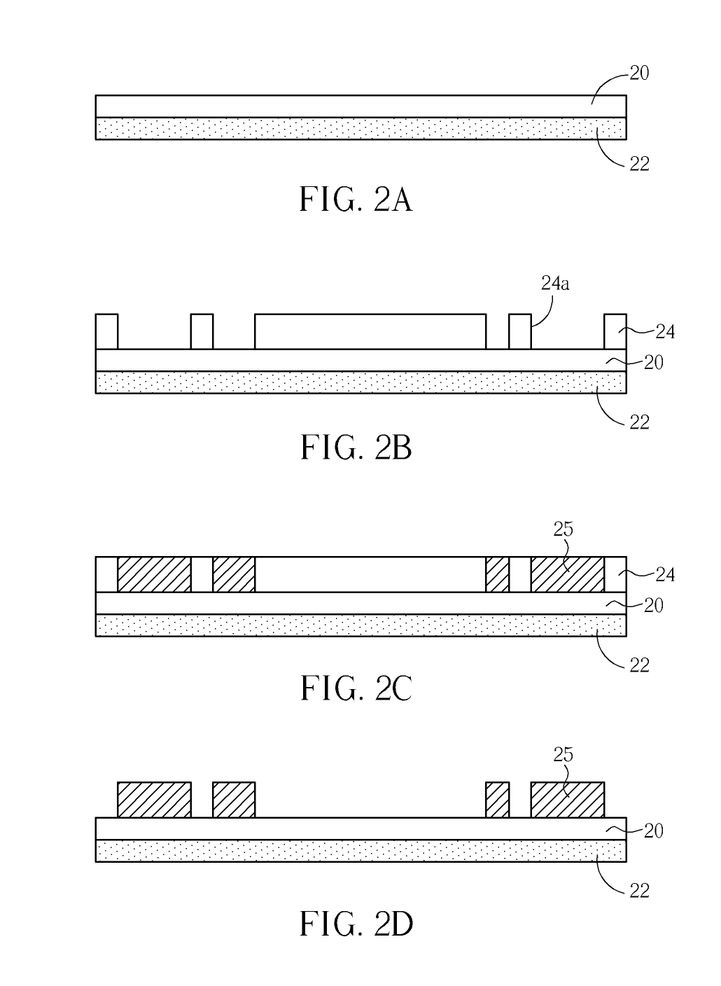

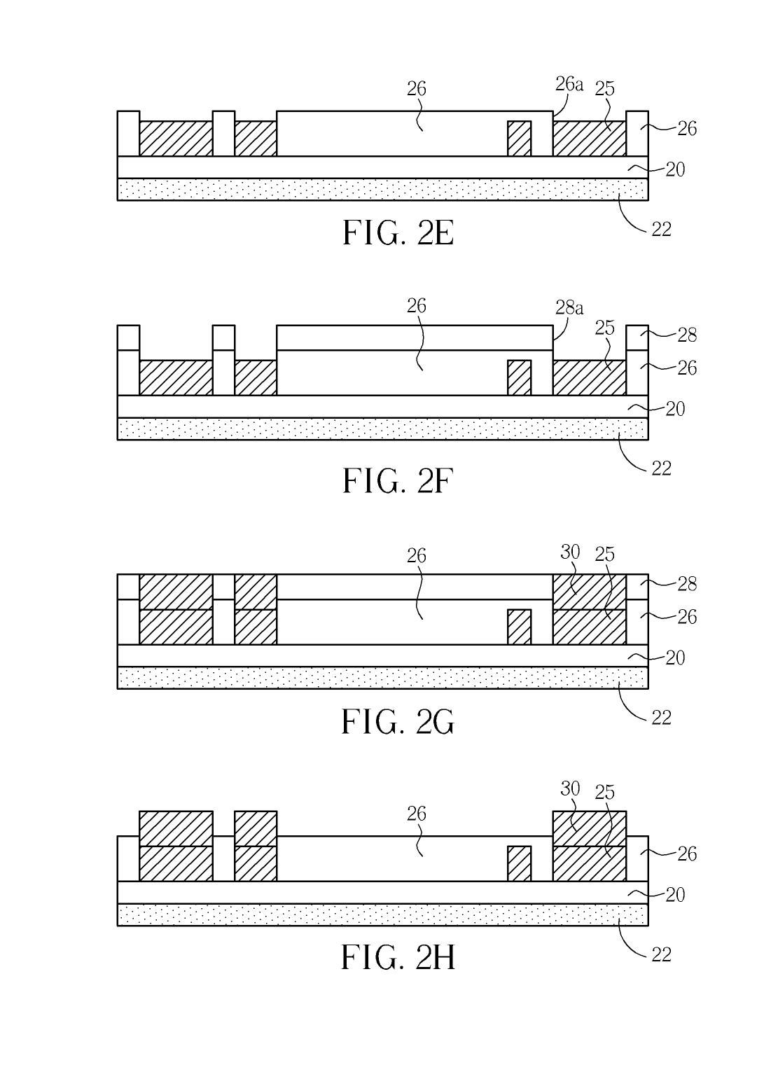

Please refer to FIGS. 2A to 2D. FIGS. 2A to 2D illustrate the process steps for forming a single-layer circuit structure of a ceramic device in accordance with a preferred first embodiment of the present invention. As shown in FIG. 2A, first adhere an unsintered layer 20 on a hot-degumming film 22, wherein the degumming and foaming temperature of the hot-degumming film 22 must be limited to 80˜110 ° C., in order to be suitable for the following processes. The unsintered layer 20 maybe a green sheet. In another embodiment, the unsintered layer 20 may also be replaced by another interlayer substrate, such as a glass substrate. Then, as shown in FIG. 2B, hot-press a dry film photoresist 24 on the unsintered layer 20 by pressing the dry film photoresist uniformly on the unsintered layer 20, with, for example, a vacuum pressure of 0 to 1 torr, at a 70° C. hot-pressing temperature and with a processing time of 20 sec. Then, form a circuit trench 24a in the dry film photoresist 24 by photolithography process, wherein the circuit trench 24a exposes apart of the unsintered layer 20. Subsequently, as shown in FIG. 2C, fill a metal paste, such as a silver paste, into the circuit trench 24a by a printing method (the printing method may or may not be screen printing process) to form circuit pattern 25. The aspect ratio of circuit pattern 25 is ranged from 0.5 to 2.5, the critical dimension circuit pattern 25 is smaller than 20 μpm, and the height of said circuit pattern is ranged from 15˜50 μm. A drying process is then performed. Subsequently, as shown in FIG. 2D, remove the dry film photoresist 24 in an alkaline solution at a temperature lower than 50˜60° C. Then, dry the semi-finished photoresist at temperature lower than 50° C. to form a single-layer circuit structure. The unsintered layer 20 and the circuit pattern 25 may be further co-fired after removing the dry film photoresist 24.

FIGS. 2E to 2H illustrate the process steps of a 2nd-level circuit structure (subsequent to FIG. 2D). As shown in FIG. 2E, print a dielectric layer 26 on the unsintered layer 20 by wet printing. The dielectric layer 26 covers part of the circuit pattern 25 and is provided with an opening 26a that exposes a part of the circuit pattern 25. The dielectric layer 26 may include magnetic powder, ceramic powder, oxide powder, etc. Subsequently, as shown in FIG. 2F, hot-press a dry film photoresist 28 on the dielectric layer 26, and form a circuit trench 28a in the dry film photoresist 28 by photolithography process. Subsequently, as shown in FIG. 2G, fill the circuit trench 28a with metal paste, such as silver paste, by a printing method, to form a circuit pattern 30. A drying process is then performed. Finally, as shown FIG. 2H, remove the dry film photoresist 28 in an alkaline solution at a temperature lower than 50˜60° C. Then dry the semi-finished photoresist at temperature lower than 50° C. to complete the 2nd-level circuit structure. The aspect ratio of 2nd-level circuit pattern structure is ranged from 0.5 to 2.5, the critical dimension of 2nd-level circuit pattern structure is smaller than 20 μm, and the height of 2nd-level circuit pattern structure is ranged from 15˜50 μm. Subsequently, the steps of FIG. 2E to 2H may be repeated to form and sinter the multilayer circuit structure into a multilayer ceramic device at a temperature comprised between 850° C. and 950° C. for silver paste or between 900° C. and 1000° C. for copper paste. At least one of said circuit structures or circuit patterns has smooth lateral sides.

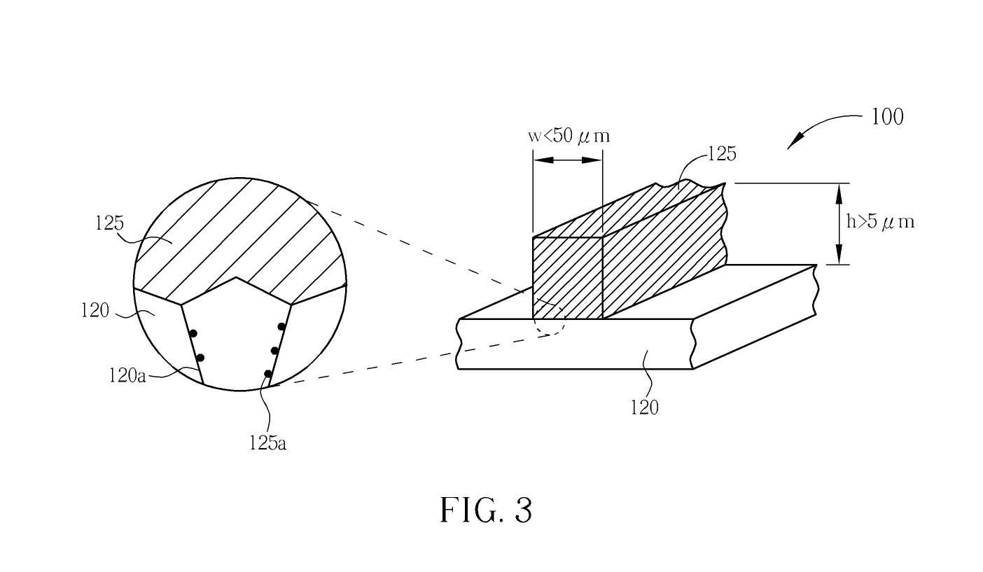

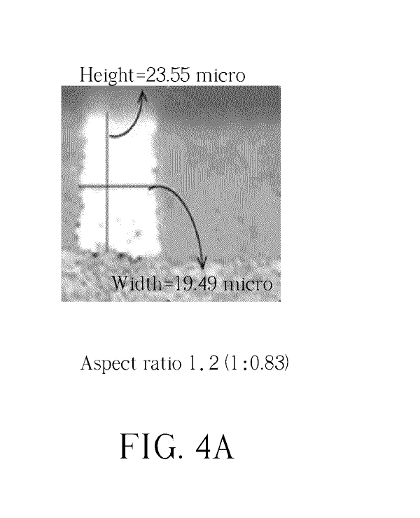

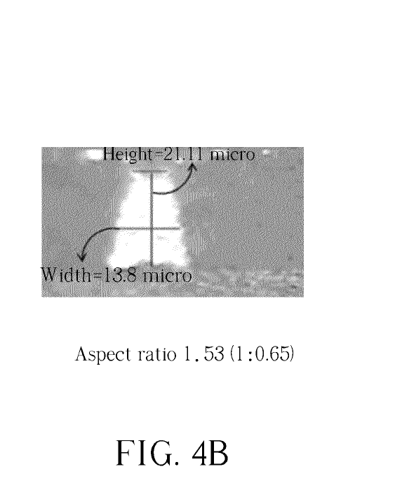

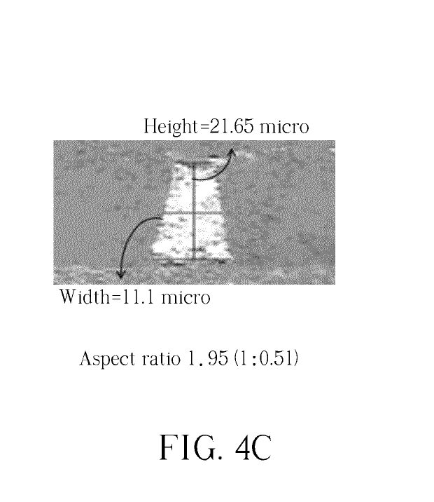

Please refer to FIG. 3 showing the cross-sectional view of the circuit structure of the ceramic device in present invention. To conveniently describe the present invention, the dielectric layer is omitted in the drawing. As shown in FIG. 3, the multi-layer ceramic device 100 in the present invention comprises at least one substrate 120 and a fine line circuit 125 formed on the surface of substrate 120, such as a silver circuit pattern, with an aspect ratio ranged from 0.5 to 2.5. The fine line circuit 125 on the multi-layer ceramic device 100 may be manufactured by following the methods described in FIG. 2A to 2H. The specificity of this structure is that the fine circuit line 125 has a high aspect ratio (h/w), wherein the width w of fine circuit line 125 may be adjusted, depending on the resolution of photolithography process. According to the embodiment of the present invention, the width w may be smaller than 50 μm, preferably smaller than 20 μpm, while the depth or height h of the fine line circuit 125 may be larger than 5 μm, preferably in a range of 15˜20 μm. If we take an example of a 20 μm width, the aspect ratio of fine circuit line 125 will at least be over 0.25, and even exceed 1.2. Besides, the metal circuit pattern may come in contact directly with the ceramic substrate. FIGS. 4A to 4C show the aspect ratio of fine line circuits with different dimensions in cross-sectional views. The metal circuit patterns are usually trapezoidal. The width of the circuit pattern is set as the medium value of height.

Furthermore, the interface of the fine line circuit 125 and substrate 120 in the present invention (portion shown in enlarged circle of FIG. 3) shows another feature of the circuit structure; that is, silver compounds 125a diffused to the grain boundary 120a due to the sintering temperature may be found in the grain boundary 120a of the substrate 120. The structure of the fine line circuit 125 cannot be obtained by conventional screen printing technology (where minimal width is about 50 μm) or plating technology. Besides, since the circuit pattern is formed by photolithography process, the circuit structure displays excellent width uniformity and high edge resolution. That is, the silver circuit pattern will has smooth lateral sides. The irregular width issue that used to occur in conventional screen printing processes may not occur with the present invention.

The main difference between the electroplating process and the co-fired structure is the microscopic structure of the conductive materials. The electroplating process requires a PVD or a CVD process to deposit a seed layer on the substrate, and then performs a plating process to grow a metal circuit along the surface of the seed layer. The direction of the grain growth is decided by the lattice structure of the seed layer; it usually is an anisotropic growth with a dense arrangement along the grains, and has high compactness in this case. The grain growth mechanism of the conductive material in the co-fired system is based on lowering the surface energy of the grain boundaries; it is a kind of isotropic growth with mainly polygonal shapes. The grain size depends on the total amount of absorbed heat (depending on the sintering temperature and time). The grain arrangement in this case is less compact, and remaining pores are observed in the sample due to incomplete binder removal.

### Embodiment 2

The present invention further provides a method for manufacturing a multi-layer ceramic device having fine line circuits and high aspect ratio, from a green sheet having a glass or a ceramic substrate. The process steps are described as follows:

Step 1: punch stack alignment pin holes on a hot-degumming sheet (or cold-degumming sheet) which is used for adhering the green ceramic.

Step 2: punch stack alignment pin holes on an outer dummy layer of green ceramic where no circuit is to be printed on.

Step 3: laminate the punched outer dummy layer of green ceramic with cold-degumming anchor pins.

Step 4: punch stack alignment pin holes, photo alignment holes and via holes on the inner layer of green ceramic where a circuit is to be printed on.

Step 5: laminate the 1st-level inner layer of green ceramic, where the circuit is to be printed on, with the green ceramic layer stack aligned on the hot-degumming sheet.

Step 6: laminate the semi-finished product of step 5 with a dry film photoresist.

Step 7: expose and develop all the surrounding photo alignment holes.

Step 8: expose and develop the dry film photoresist to form circuit trenches.

Step 9: Cover the non-printed area with a screen emulsion, fill the circuit trenches with silver paste and then perform a drying process to form a silver circuit pattern, wherein said silver circuit pattern may be spiral shaped.

Step 10: develop and remove the dry film photoresist.

Step 11: press the semi-finished product of the previous step on another 2nd-level inner layer of green ceramic where a circuit is to be printed on.

Step 12: laminate the semi-finished product of step 11 with a dry film photoresist.

Step 13: repeat steps 7 through 13.

Step 14: press on another outer dummy layer of green ceramic where no circuit is to be printed on.

Step 15: laminate by isostatic pressing.

Step 16: cut.

Step 17: remove the hot-degumming film.

Step 18: sinter.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a ceramic device, comprising the steps of:
providing an unsintered layer;
coating a photoresist on said unsintered layer;
forming a circuit trench in said photoresist by lithography process;
filling said circuit trench with a metal paste to forma circuit pattern; and
removing said photoresist.

2. The method of claim 1, wherein said unsintered layer is a green sheet.

3. The method of claim 1, further comprising co-firing said unsintered layer with circuit pattern after removing said photoresist.

4. The method of claim 1, wherein said photoresist is a dry film photoresist.

5. The method of claim 4, wherein said dry film photoresist is coated on said unsintered layer by hot pressing.

6. The method of claim 1, wherein said metal paste is silver paste.

7. The method of claim 1, wherein said metal paste is filled in said circuit trench by printing.

8. The method of claim 1, wherein the aspect ratio of said circuit pattern is ranged from 0.5 to 2.5.

9. The method of claim 1, wherein the critical dimension said circuit pattern is smaller than 20 μm.

10. The method of claim 1, further comprising the step of performing a drying process at a temperature lower than 50° C. after removing said photoresist.

11. The method of claim 1, wherein the height of said circuit pattern is ranged from 15˜50 μm.

12. The method of claim 1, wherein said circuit pattern has smooth lateral sides.

13. The method of claim 12, wherein the width of said circuit pattern is smaller than 50 μm, and the height of said silver circuit pattern is larger than 5 μm.

14. The method of claim 12, wherein the grain boundary of said ceramic device contains silver compounds.

15. A method of manufacturing a ceramic device, comprising the steps of:
providing an unsintered layer;
covering a first photoresist on said unsintered layer;
forming a first circuit trench in said first photoresist by lithography process;
filling a first metal paste in said first circuit trench to form a first circuit pattern;
removing said first photoresist;
forming a dielectric layer on said unsintered layer and said first circuit pattern, wherein said dielectric layer includes an opening exposing a portion of said first circuit pattern;
covering a second photoresist on said dielectric layer;
forming a second circuit trench in said second photoresist by lithography process;
filling a second metal paste in said second circuit trench to form a second circuit pattern; and
removing said second photoresist.

16. The method of claim 15, wherein the critical dimension of said first circuit pattern or said second circuit pattern is smaller than 20 μm.

17. The method of claim 15, wherein the height of said first circuit pattern or said second circuit pattern is ranged from 15˜50 μm.

18. The method of claim 15, wherein the aspect ratio of said first circuit pattern or said second circuit pattern is ranged from 0.5 to 2.5.

19. The method of claim 15, further comprising the step of performing a drying process at a temperature lower than 50° C. after removing said first photoresist or said second photoresist.

20. The method of claim 15, wherein at least one of said first or second circuit pattern has smooth lateral sides.
